(19) United States
(12) Patent Application Publication
(10) Pub. No.: US 2019/0057463 A1
(43) Pub. Date: Feb. 21, 2019

(54) SYSTEMS AND METHODS FOR PROVIDING SOLAR ENERGY GENERATION INFRASTRUCTURE TO CUSTOMERS AS A SERVICE

(71) Applicant: Latifullah Khan, (US)

(72) Inventors: Latifullah Khan, Brooklyn, NY (US); Imran Shahid Gul, Dubai (AE)

(21) Appl. No.: 16/105,986

(22) Filed: Aug. 21, 2018

Related U.S. Application Data
(60) Provisional application No. 62/547,890, filed on Aug. 21, 2017.

(51) Int. Cl. G06Q 50/06; H02J 3/38; H01L 31/042; G06Q 10/04

(52) U.S. Cl. CPC G06Q 50/06; G06Q 10/04; H01L 31/042; H02J 3/383

(57) ABSTRACT

Systems and methods for providing, by an infrastructure provider, a solar energy generation infrastructure to customers as a service are disclosed. The system includes an input module for receiving a request including at least one of a solar energy requirement and a billing information from a customer; a request processing module for processing the request by identifying and presenting a list of infrastructure providers to the customer for selecting an infrastructure provider from the list; a costing and payment module for: determining an infrastructure cost comprising a one-time materials' cost and a maintenance cost, the one-time materials' cost including a cost of the one or more solar energy generation infrastructure; and receiving a payment according to the infrastructure cost; and an allocation module configured to allocate the one or more solar energy generation infrastructure to a customer account associated with the customer.

### TECHNICAL FIELD

The presently disclosed embodiments relate to the field of solar energy generation. More specifically, embodiments of the present disclosure relate to systems and methods for selling, by an infrastructure provider, one or more solar energy generation resources as a service to a plurality of customers for producing renewable power. The one or more solar energy generation resources are installed at premises of an infrastructure provider.

### BACKGROUND

The energy sources can be non-renewable energy sources and renewable energy sources. The supply of the non-renewable energy sources available to the world or societies is limited and is being used faster than they can be replaced. The non-renewable energy sources when used for generating energy may release pollutants including gases, like carbon dioxide, carbon monoxide, and other greenhouse gases, into the atmosphere causing global temperatures to rise. Moreover, the non-renewable resources are limited in supply and are exhausting at a very high speed.

On the other hand, the renewable energy sources are virtually limitless, such as the sun, which will continue to shine for years. Examples of the renewable energy sources include, but are not limited to, water, wind, sun, biomass, geothermal, and so forth. The renewable energy sources are available in much abundance or they can be replaced so rapidly that they can't run out. The use of renewable energy sources suffers from some limitations. For example, installing panels renewable energy/solar energy generation infrastructure require large land for installation that is usually a challenge within urban areas. Further, the installation and maintenance of the infrastructure is usually costly and complex. Currently, to generate power and electricity from the solar energy requires installation of large solar panels, AC/DC converters, a number of ATS switching devices, DC wiring, and so forth. This may require a lot of infrastructure installation including such as, but not limited to, lot of space, modification of architecture to building appearance, a location getting sun light in abundance, regulations and permits. Further, installation of renewable energy generation infrastructure may sometimes modify architecture of building appearance where they are installed. In some scenarios, the location of the people has poor or inadequate access to full daylight sun; hence if renewable energy generation infrastructure is installed at such location then solar energy generation becomes difficult or impossible. In addition, the people may have to take permits and regulations for installing the renewable energy generation infrastructure. Therefore it's challenging for the people to install, acquire, maintain, and take permits for installing the renewable energy generation infrastructure at their personal premises. Hence, they are skeptical to switch to renewable energy.

Due to the limitations involved in installing the infrastructure, not many individuals are able to install the infrastructure at their end such as, home or offices. In turn, the individuals are dependent on city power providers, such as the Municipality that usually rely on non-renewable sources of energy for generating electricity, for their electricity requirements. This results in more pollutants added into the environment everyday and worsening the pollution issue.

### SUMMARY

In light of above discussion, there exists need for quick, swift, and cost effective solution for resolving the existing environmental issues by providing individuals to use solar energy for their daily electricity/power needs without getting into complexities of high cost of infrastructure installation and maintenance. As discussed, there arises a need for techniques for selling a plurality of solar energy generation resources or infrastructure as a service to a plurality of customers for producing renewable power. The plurality of solar energy generation resources or infrastructure may be installed at a centrally managed location that may be managed by an infrastructure provider.

An objective of the present disclosure is to allow a plurality of customers facing one or more challenges for producing their own solar energy at their location to buy solar energy generation resources or infrastructure from an infrastructure provider. The physical solar energy generation infrastructure including solar energy generation panels are separated from a point of consumption of the solar energy and are placed in a centrally managed location for the purpose of sharing key supporting services and devices. The present disclosure in this way allows the customers who wish to be an energy produced of any size, and to inherit the benefits of producing their own clean renewable energy or power.

Another objective of the present disclosure is to provide a solar energy generation infrastructure to a number of customers as a service. The solar energy generation infrastructure is provided and managed by an infrastructure provider. The infrastructure provider may allocate one or more solar energy generation infrastructure to the customer requesting for the same. After allocation, the solar energy or the renewable power produced by the allocated solar energy generation infrastructure is metered and supplied for consumption to a location/premise of the customer. The location of the customer may include, but are not limited to, a home, an office, an apartment, a factory, and so forth.

The present disclosure provides systems and methods for selling, by an infrastructure provider, solar energy generation infrastructure or resources to a plurality of customers as a service for producing solar energy.

The present disclosure also provides systems and methods for buying, by a plurality of customers, a plurality of solar energy generation infrastructure or resources from an infrastructure provider as a service for producing solar energy.

Further, the present disclosure provides systems and methods for enabling a plurality of customers to produce solar energy by using one or more solar energy generation resources as a service. The one or more solar energy generation resources may be installed at a remote centrally managed location that may be managed by an infrastructure provider.

Furthermore, the present disclosure provides systems and methods for enabling a customer to buy a plurality of solar energy generation resources or infrastructure as a service or product from an infrastructure provider for producing their own renewable power. The resources/infrastructure are installed at a premise or a centrally managed location of the infrastructure provider. The resources/infrastructure are installed and maintained by the infrastructure provider with all permits and regulations from a concerned regulatory department. The customers may not have to manage installation of the solar energy generation resources. The customers can directly pay a fee and use the solar energy generation resources of the infrastructure provider without physically installing the resources at their end. Hence, its cost effective and time saving for the customers.

The present disclosure provides a virtual resource providing system for managing and installing a plurality of solar energy generation resources at a premise or a centrally managed location of an infrastructure provider on behalf of a plurality of customers for generating renewable power. The solar energy generation resources are purchased by the plurality of customers as a service or a product from the infrastructure provider as per their own requirement.

The present disclosure provides a method for managing and installing a plurality of solar energy generation resources at a or a centrally managed location of an infrastructure provider on behalf of a plurality of customers for generating renewable power. The solar energy generation resources are purchased by the plurality of customers as a service or a product from the infrastructure provider.

The present disclosure provides a virtual resource providing system for selling a plurality of solar energy generation resources/infrastructure installed at a centrally managed location of an infrastructure provider on behalf of a plurality of customers as a service for generating renewable power that may be consumed by the customers. The renewable power produced is supplied directly to the customers.

The present disclosure provides a method for selling a plurality of solar energy generation resources installed at a centrally managed location of an infrastructure provider as a service to a plurality of customers for generating renewable power on behalf of a plurality of customers.

An embodiment of the present disclosure provides a system for selling, by an infrastructure provider, a plurality of solar energy generation resources to a plurality of customers as a service. The system includes an input module configured to receive a request including at least one of a solar energy requirement and a billing information from at least one customer of the plurality of customers. The at least one customer provides the solar energy requirement via a customer interface. The system also includes a request processing module configured to process the request by identifying and presenting a plurality of infrastructure providers to the at least one customer based on the request. The at least one customer selects at least one infrastructure provider of the plurality of infrastructure providers. The system also includes a costing and payment module configured to: determine an infrastructure cost comprising a one-time materials' cost and a maintenance cost; and receive a payment for the one or more solar energy generation resources according to the infrastructure cost from the at least one customer. The one-time materials' cost may include a cost of one or more solar energy generation resources/infrastructure including a number of solar panels, a wiring, an invertor, ATS switching devices, converter, a grid access, an end-to end service, a health monitoring service, a first smart meter, and a second smart meter based on the received request. The system also includes an allocation module configured to allocate the one or more solar energy generation resources according to the received request to a customer account associated with the at least one customer.

Another embodiment of the present disclosure provides virtual resource providing system for selling a plurality of solar energy generation resources installed at a centrally managed location of an infrastructure provider as a service for generating renewable power on behalf of a plurality of customers. The virtual resource providing system includes an input module configured to receive a request comprising at least one of a solar energy requirement and a billing information from at least one customer of a plurality of customers. The at least one customer may provide the solar energy requirement via a customer interface. The virtual resource providing system also includes a request processing module configured to process the request by identifying and presenting a list comprising a plurality of infrastructure providers to the at least one customer based on the request. The at least one customer may select at least one infrastructure provider from the list. The virtual resource providing system also includes a costing and payment module configured to: an infrastructure cost comprising a one-time materials' cost and a maintenance cost, the one-time materials' cost comprising a cost of one or more solar energy generation resources comprising a plurality of solar panels, a wiring, an invertor, an AC/DC converter, a grid access, ATS switching devices, an end-to end service, a health monitoring service, a first smart meter, and a second smart meter based on the received request; and receive a payment for the one or more solar energy generation resources according to the infrastructure cost from the at least one customer. The virtual resource providing system also includes an allocation module configured to allocate the one or more solar energy generation resources according to the received request to a customer account associated with the at least one customer. The virtual resource providing system also includes an infrastructure managing module configured to manage the one or more solar energy generation resources on behalf of the at least one customer to ensure operations and a consistent solar energy flow; and provide a plurality of support services comprising a repairing service, and a warranty service to the at least one customer post allocation of the one or more solar energy generation resources.

Another embodiment of the present disclosure provides a method for method for selling a plurality of solar energy generation resources as a service to a plurality of customers. The method includes a receiving, by an input module, a request comprising at least one of a solar energy requirement and a billing information from at least one customer of the plurality of customers, wherein the at least one customer provides the solar energy requirement via a customer interface. The method also includes processing, by a request processing module, the request by identifying and presenting a plurality of infrastructure providers to the at least one customer based on the request, wherein the at least one customer selects at least one infrastructure provider of the plurality of infrastructure providers. The method further includes determining, by a costing and payment module, an infrastructure cost comprising a one-time materials' cost and a maintenance cost, the one-time materials' cost comprising a cost of one or more solar energy generation resources comprising a plurality of solar panels, a wiring, an invertor, an ATS switching devices, converter, a grid access, an end-to end service, a health monitoring service, a first smart meter, and a second smart meter based on the received request. The method also includes receiving, by the costing and payment module, a payment for the one or more solar energy generation resources according to the infrastructure cost from the at least one customer. The method also includes allocating, by an allocation module, the one or more solar energy generation resources according to the received request to a customer account associated with the at least one customer.

Another embodiment of the present disclosure provides a method for selling a plurality of solar energy generation resources installed at a centrally managed location of an infrastructure provider as a service for generating renewable power on behalf of a plurality of customers. The method includes receiving a request comprising at least one of a solar energy requirement and a billing information from at least one customer of a plurality of customers, wherein the at least one customer provides the solar energy requirement via a customer interface. The method also includes processing the request by identifying and presenting a list comprising a plurality of infrastructure providers to the at least one customer based on the request, wherein the at least one customer selects at least one infrastructure provider of the plurality of infrastructure providers. The method further includes determining an infrastructure cost comprising a one-time materials' cost and a maintenance cost, the one-time materials' cost comprising a cost of one or more solar energy generation resources comprising a plurality of solar panels, a wiring, an invertor, an AC/DC converter, a grid access, ATS switching devices, an end-to end service, a health monitoring service, a first smart meter, and a second smart meter based on the received request. The method furthermore includes receiving a payment for the one or more solar energy generation resources according to the infrastructure cost from the at least one customer. The method also includes allocating the one or more solar energy generation resources according to the received request to a customer account associated with the at least one customer. The method also includes managing the one or more solar energy generation resources on behalf of the at least one customer to ensure operations and a consistent solar energy flow. The method further includes providing a plurality of support services comprising a repairing service, and a warranty service to the at least one customer post allocation of the one or more solar energy generation resources.

Another embodiment of the present disclosure provides a method for enabling a customer to buy a plurality of solar energy generation resources as a service from an infrastructure provider. The method includes accessing a virtual resource providing system on a computing device for entering a request comprising at least one of a solar energy requirement and a billing information, wherein a customer provides the solar energy requirement via a customer interface. The method also includes receiving a list of a plurality of infrastructure providers capable of providing one or more solar energy generation resources required to generate solar energy according to the received request. The customer may select at least one infrastructure provider from the list. Further, the one or more solar energy generation resources may include a plurality of solar panels, a wiring, an invertor, an AC/DC converter, a grid access, ATS switching devices, an end-to end service, a health monitoring service, a first smart meter, and a second smart meter based on the received request. The method also includes receiving an infrastructure cost comprising a one-time materials' cost and a maintenance cost. The one-time materials' cost may include a cost of the one or more solar energy generation resources. The method further includes making a payment according to the infrastructure cost via the virtual resource providing system. The one or more solar energy generation resources may be allocated to a customer account associated with the customer after a successful processing of the payment. The one or more solar energy generation resources may be located remotely from the customer and are managed by the infrastructure provider on behalf of the customer.

According to an aspect of the present disclosure, the plurality of solar panels allocated to the customer is metered using at least one of a smart metering and a net metering technology.

According to another aspect of the present disclosure, each of the solar panels that the infrastructure provider installs on behalf of the customer is identified or assigned with a unique panel identifier to ensure that the allocated solar panels belonging to the particular customer only who has paid for the solar panels.

According to another aspect of the present disclosure, the infrastructure provider do all the wiring, solar panels' installation or allocation, provide end-to-end services and grid access.

According to another aspect of the present disclosure, the first smart meter and the second smart meter installed for the customers are metered using a smart meter or a net metering technology.

According to another aspect of the present disclosure,

According to a further aspect of the present disclosure, the first smart meter installed at an infrastructure end is configured to measure/meter power produced by the allocated one or more solar energy generation resources.

According to another aspect of the present disclosure, the second smart meter installed at a customer end is configured to measure/meter power consumed by the allocated one or more solar energy generation resources.

According to a further aspect of the present disclosure, the first smart meter and the second smart meter are associated with a same meter identifier assigned by a city power provider comprising a municipality; the city power provider keeps a track of a reading on the first smart meter and the second smart meter.

According to a further aspect of the present disclosure, the customer can search one or more infrastructure providers capable of providing or selling one or more solar energy generation resources according to a request.

According to yet another aspect of the present disclosure, the virtual resource providing system is a cloud-based application.

According to another aspect of the present disclosure, the virtual resource providing system is accessible via a website and a uniform resource locator (URL).

According to a further aspect of the present disclosure, the customers access the virtual resource providing system on an associated computing device for buying one or more solar energy generation resources.

According to another aspect of the present disclosure, each of the plurality of customers access the virtual resource providing system via at least one of a browsing application and a direct access application running on a computing device associated with the customers.

According to an aspect of the present disclosure, a platform is provided that enables the customers to buy solar energy generation resources/infrastructure from an infrastructure provider for saving the customers from getting into complexities of installation and arranging land space for the solar energy generation resources/infrastructure for generating renewable power.

According to another aspect of the present disclosure, the one or more solar energy generation resources are located remotely from the customer and are managed by the infrastructure provider on behalf of the at least one customer.

According to another aspect of the present disclosure, the system includes a database configured to store information of plurality of customer accounts of the plurality of customers, a plurality of computing devices associated with the plurality of customers, the plurality of infrastructure providers, a login credential of each of the plurality of customers, a consumption and production information of the solar energy for each of the plurality of customers, and the plurality of solar energy generation resources.

According to an aspect of the present disclosure, the plurality of customers comprises at least one of a plurality of industries, and an individual person.

According to another aspect of the present disclosure, the payment is received via a payment gateway.

According to a further aspect of the present disclosure, the allocation module is configured to at least one of install and allocate the one or more solar energy generation resources on behalf of the at least one customer at a centrally managed location of the at least one infrastructure provider as per the received request; assign a unique resource identifier to the allocated one or more solar energy generation resources; and attach the plurality of solar panels with the first smart meter and the second smart meter for measuring renewable power produced and renewable power consumed, respectively, wherein the first smart meter and the second smart meter are associated with a same meter identifier assigned by a city power provider comprising a municipality.

According to a further aspect of the present disclosure, the solar panels are installed at a centrally managed location that is cost effective, have easy access to the full daylight sun and receive the sunlight in abundance for generating renewable power.

According to an embodiment of the present disclosure, the system also includes an infrastructure managing module configured to: manage the one or more solar energy generation resources on behalf of the at least one customer to ensure operations and a consistent solar energy flow; and provide a plurality of support services comprising a repairing service, and a warranty service to the at least one customer post allocation of the one or more solar energy generation resources.

According to an embodiment of the present disclosure, the allocation module of the system is also configured to de-allocate the one or more solar energy generation resources based on a de-allocation request received from the at least one customer.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified.

For a better understanding of the present invention, reference will be made to the following Detailed Description, which is to be read in association with the accompanying drawings, wherein:

FIG. 1 illustrates an exemplary environment where various embodiments of the present disclosure may function;

FIG. 2 illustrates another exemplary environment where various embodiments of the present disclosure may function;

FIG. 3 illustrates another exemplary environment where various embodiments of the present disclosure may function;

FIG. 4 is a block diagram illustrating system elements of an exemplary virtual resource providing system, in accordance with an embodiment of the present disclosure.

FIG. 5A is a block diagram illustrating system elements of an exemplary computing device, in accordance with an embodiment of the present disclosure;

FIG. 5B is a block diagram illustrating system elements of another exemplary computing device including the virtual resource providing system of FIG. 4, in accordance with another embodiment of the present disclosure;

FIGS. 6A-6B illustrates a flowchart of a method of buying, by a customer, one or more solar energy generation resources as a service by using the virtual resource providing system of FIG. 4, in accordance with an embodiment of the present disclosure;

FIGS. 7A-7B illustrates a flowchart of a method of selling and managing, by an infrastructure provider, one or more solar energy generation resources as a service by using the virtual resource providing system of FIG. 4, in accordance with an embodiment of the present disclosure; and

FIGS. 8A-8B illustrates a flowchart of a method of adjusting units of renewable power produced for one or more units of non-renewable power supplied to a customer by a city power provider, in accordance with an embodiment of the present disclosure.

The headings used herein are for organizational purposes only and are not meant to be used to limit the scope of the description or the claims. As used throughout this application, the word “may” is used in a permissive sense (i.e., meaning having the potential to), rather than the mandatory sense (i.e., meaning must). To facilitate understanding, like reference numerals have been used, where possible, to designate like elements common to the figures.

### DETAILED DESCRIPTION

The presently disclosed subject matter is described with specificity to meet statutory requirements. However, the description itself is not intended to limit the scope of this patent. Rather, the inventors have contemplated that the claimed subject matter might also be embodied in other ways, to include different steps or elements similar to the ones described in this document, in conjunction with other present or future technologies. Moreover, although the term “step” may be used herein to connote different aspects of methods employed, the term should not be interpreted as implying any particular order among or between various steps herein disclosed unless and except when the order of individual steps is explicitly described.

Reference throughout this specification to “a select embodiment”, “one embodiment” or “an embodiment” means that a particular feature, structure, or characteristic described in connection with the embodiment is included in at least one embodiment of the disclosed subject matter. Thus, appearances of the phrases “a select embodiment” “in one embodiment” or “in an embodiment” in various places throughout this specification are not necessarily referring to the same embodiment.

Furthermore, the described features, structures, or characteristics may be combined in any suitable manner in one or more embodiments. In the following description, numerous specific details are provided, to provide a thorough understanding of embodiments of the disclosed subject matter. One skilled in the relevant art will recognize, however, that the disclosed subject matter can be practiced without one or more of the specific details, or with other methods, components, materials, etc. In other instances, well-known structures, materials, or operations are not shown or described in detail to avoid obscuring aspects of the disclosed subject matter.

All numeric values are herein assumed to be modified by the term “about,” whether or not explicitly indicated. The term “about” generally refers to a range of numbers that one of skill in the art would consider equivalent to the recited value (i.e., having the same or substantially the same function or result). In many instances, the terms “about” may include numbers that are rounded to the nearest significant figure. The recitation of numerical ranges by endpoints includes all numbers within that range (e.g., 1 to 5 includes 1, 1.5, 2, 2.75, 3, 3.80, 4, and 5).

As used in this specification and the appended claims, the singular forms “a,” “an,” and “the” include or otherwise refer to singular as well as plural referents, unless the content clearly dictates otherwise. As used in this specification and the appended claims, the term “or” is generally employed to include “and/or,” unless the content clearly dictates otherwise.

The following detailed description should be read with reference to the drawings, in which similar elements in different drawings are identified with the same reference numbers. The drawings, which are not necessarily to scale, depict illustrative embodiments and are not intended to limit the scope of the disclosure.

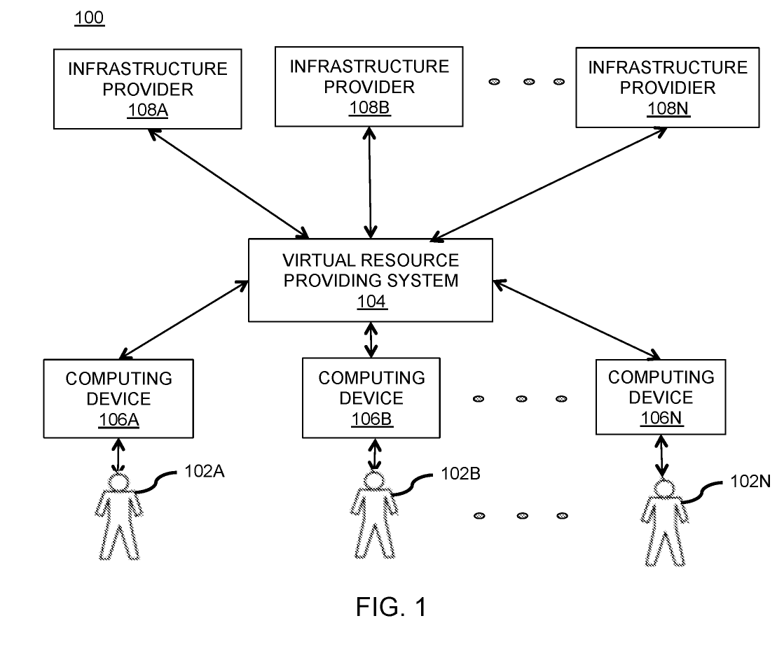

FIG. 1 illustrates an exemplary environment 100 where various embodiments of the present disclosure may function. The environment primarily includes a number of customers 102A-102N, a virtual resource providing system 104, a number of computing devices 106A-106N associated with the customers 102A-102N, and a number of infrastructure providers 108A-108N. The customers 102A-102N can be individual users, and industries. Examples of the computing devices 106A-106N include, but are not limited to, a smart phone, a mobile electronic device, a computer, a laptop, a tablet, a phablet, and so forth. The customers 102A-102N may be individuals or industries facing one or more challenges for producing their own renewable power at their own location by using solar energy/sun.

The virtual resource providing system 104 allows the customers 102A-102N to rent or use one or more solar energy generation resources or infrastructure of the infrastructure providers 108A-108N by paying a fee including infrastructure cost. The infrastructure providers 108A-108N may provide key supporting shared services and devices to allow the customers 102A-102N to produce be a renewable power of any size, and to inherit the benefits of producing their own renewable power/energy. The virtual resource providing system 104 separates the physical solar panels from the point of consumption and places these panels in a centrally managed location that may be maintained by the infrastructure providers 108A-108N. Further, the infrastructure providers 108A-108N may install the solar energy generation resources or infrastructure in such locations that are cost effective and have easy access to the full daylight sun. Further, the infrastructure providers 108A-108N may install and manage the solar panels on behalf of the customers 102A-102N, do all the wiring, and provide end-to-end services and grid access to the customers 102A-102N. Furthermore, the infrastructure providers 108A-108N take each of the solar panels that they install on behalf of the customer and identify that panel as belonging to the purchasing customer, such as the customer 102A.

In some embodiments, the virtual resource providing system 104 may be an application running on the computing devices 106A-106N. In alternative embodiments, the virtual resource providing system 104 is a server remotely located or a website and can be accessed via a browsing application on the computing devices 106A-106N. Further, the virtual resource providing system 104 can be software, hardware, firmware, or combination of these. Furthermore, the virtual resource providing system 104 can be a single device or a combination of multiple devices. The infrastructure providers 108A-108N are the suppliers or providers of a number of solar energy generation resources. The infrastructure providers 108A-108N may sell the solar energy generation resources to the customers 102A-102N via the virtual resource providing system 104.

The customers 102A-102N may access the virtual resource providing system 104 on their computing devices 106A-106N by opening an application or via a website. In some embodiments, the infrastructure providers 108A-108N and the customers 102A-102N register with the website of the virtual resource providing system 104 for accessing the virtual resource providing system 104. In some embodiments, the infrastructure providers 108A-108N and the customers 102A-102N can access the virtual resource providing system 104 without any registration process.

Further, the infrastructure providers 108A-108N and the customers 102A-102N may access the virtual resource providing system 104 by entering their unique login credentials. Each of the customers 102A-102N has an associated customer account with the virtual resource providing system 104. Further, the customers 102A-102N can enter a request comprising at least one of a solar energy requirement and a billing information or any other details on their associated computing devices 106A-106N. For example, the customer 102 can enter a request on the computing device 106A. The customers 102A-102N can enter how much renewable power they typically consume, if they don't know, they can simply enter their billing information or other form of data to get the total energy consumption.

The virtual resource providing system 104 (hereinafter also referred as system 104, without change in its meaning) is configured to receive requests comprising at least one of a solar energy requirement and a billing information from at least one customer such as the customer 102A of the plurality of customers 102A-102N. In an exemplary scenario, the customer 102A may provide the solar energy requirement (also referred as renewable power requirement) and billing information via a customer interface on the computing device 106A. The virtual resource providing system 104 may then convert the entered information into a number of solar panel units (SPU) and the customers 102A-102N can then decide to produce either 100% or some fraction of their total renewable power requirement (or solar energy requirement). Further, the virtual resource providing system 104 is also configured to process the request by identifying and presenting a list including the infrastructure providers 108A-108N to the customer 102A based on the request. The infrastructure providers 108A-108N are capable of providing one or more solar energy generation resources or infrastructure as per the request. The customer 102A may select at least one infrastructure provider such as the infrastructure provider 108A from the list. In some embodiments, the customer 102A maybe provided with a number of solar panels needed for generating the renewable power as per the received request. Then, the customer 102A may choose to produce 100% or some fraction of the renewable power.

The virtual resource providing system 104 is further configured to determine an infrastructure cost including a one-time materials' cost and a maintenance cost. The one-time materials' cost may include a cost of one or more solar energy generation resources including a number of solar panels, a wiring, an invertor, an AC/DC converter, ATS switching devices, a grid access, an end-to end service, a health monitoring service, a first smart meter, and a second smart meter based on the received request. Examples of the panels may include, but are not limited to, poly panels, mono panels. Further, the panels may be of Grade level A, B, C, and D. Examples of the invertors may include, but are not limited to, centralized invertors, string invertors, and power optimizers. Further, the solar energy generation resources may include a mounting system and installation services. Examples of the mounting system may include, but are not limited to, roof mounting system, ground mounting system, and solar tracker system.

The virtual resource providing system 104 may receive a payment for the one or more solar energy generation resources according to the infrastructure cost from the at least one customer 102A. In some embodiments, the payment is received via a payment gateway. The virtual resource providing system 104 may allocate the one or more solar energy generation resources/infrastructure according to the received request to a customer account associated with the at least one customer 102. Once payment is done and received, the virtual resource providing system 104 may provision the required number of solar panels and connect them to all the necessary supporting infrastructure such as, but not limiting to, a shared inverter, a shared grid access, and health monitoring services, and provision the needed metering devices comprising the first and second smart meters.

Further, the virtual resource providing system 104 may manage the allocated solar energy generation resources and panels on behalf of the customer 102A for ensuring operations, consistent energy flow. Further, the virtual resource providing system 104 may also provide any remediation services such as repair, support, warranty services, and so forth. Further, the customer 102A can recall his/her solar energy generation resources at any time if he/she wants to move or decommission service by raising a de-allocation request at the virtual resource providing system 104.

Further, the virtual resource providing system 104 is configured to store information of plurality of customer accounts of the plurality of customers 102A-102N, the computing devices 108A-108N associated with the customers 102A-102N, the infrastructure providers 108A-108N, a login credential of each of the customers 102A-102N, a consumption and production information of the solar energy for each of the customers 102A-102N, and the solar energy generation resources.

Further, the one or more solar energy generation resources may be located remotely from the at least one customer 102A and are managed by the infrastructure provider 108A on behalf of the at least one customer 102A. Further, a number of solar panels may be installed at a centrally managed location of the infrastructure provider 108A that is cost effective, have easy access to the full daylight sun and receive the sunlight in abundance for generating renewable power. The renewable power may be a power or electricity produced by using renewable sources of energy such as, but not limiting to, the Sun.

The infrastructure provider 108A via the virtual resource providing system 104 may install and allocate the one or more solar energy generation resources on behalf of the at least one customer 102A at a centrally managed location of the at least one infrastructure provider 108A as per the received request. The virtual resource providing system 104 may further assign a unique resource identifier to the allocated one or more solar energy generation resources. The virtual resource providing system 104 may further attach the solar panels with the first smart meter and the second smart meter for measuring renewable power produced and renewable power consumed, respectively. In some embodiments, the solar panels allocated to the at least one customer 102A are metered by using at least one of a smart metering and a net metering technology.

In some embodiments, the infrastructure provider 108A via the virtual resources providing system 104 is configured to manage the one or more solar energy generation resources on behalf of the at least one customer 102A to ensure operations and a consistent solar energy flow. The virtual resources providing system 104 may also be configured to provide a plurality of support services comprising a repairing service, and a warranty service to the at least one customer 102A post allocation of the one or more solar energy generation resources. Further, in some embodiments, the virtual resource providing system 104 may be configured to de-allocate the one or more solar energy generation resources based on a de-allocation request received from the at least one customer 102A.

According to an aspect of the present disclosure, the customers 102A-102N may save the un-used renewable power for future use. In some embodiments, the customers 102A-102N can sell the un-used renewable power to other users. In some embodiments, the customers 102A-102N can pay their utility bills such as, but not limited to, an electricity bill by using the un-used renewable power which is produced by the solar energy generation resources or infrastructure purchased by the customers 102A-102N.

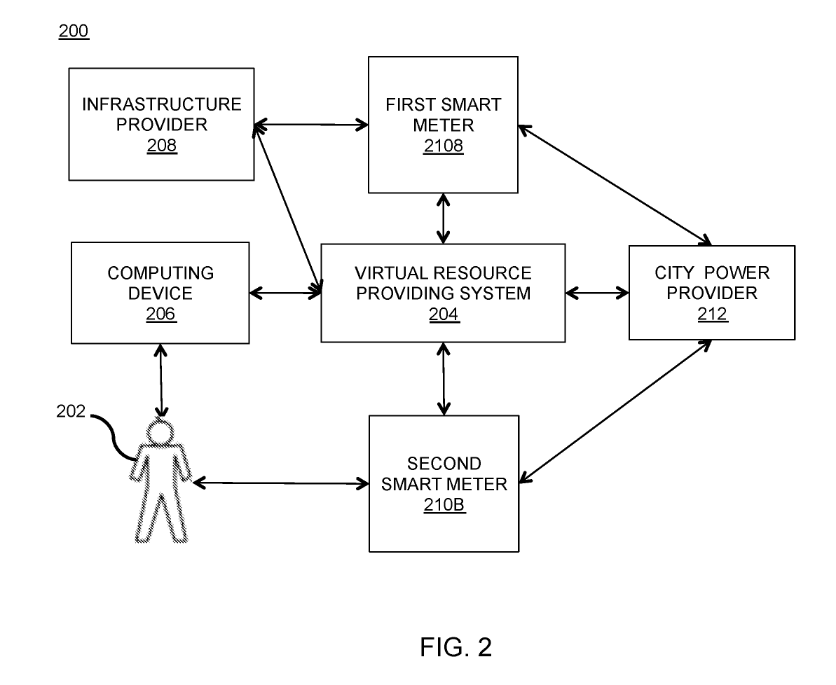

FIG. 2 illustrates another exemplary environment 200 where various embodiments of the present disclosure may function. As shown, the environment 200 primarily includes a customer 202, a computing device 206 associated with the customer 202, a virtual resource providing system 204, an infrastructure provider 208, a city power provider 212, a first smart meter 210A installed at a premise or centrally managed location of the infrastructure provider 208, and a second smart meter 210B installed at a premise or home of the customer 202. The city power provider 212 can be a municipality department of a city.

As discussed with reference to FIG. 1, the virtual resource providing system 204 is similar in functionality and structure to the virtual resource providing system 104. Further, the customer 202 can submit a request at the computing device 206 by entering a solar energy requirement or other details via the virtual resource providing system 204. The virtual resource providing system 204 may install and allocate the one or more solar energy generation resources on behalf of the customer 202 at a centrally managed location of the infrastructure provider 208 as per the received request. The virtual resource providing system 204 may further assign a unique resource identifier to the allocated one or more solar energy generation resources. The virtual resource providing system 204 may further attach the solar panels with the first smart meter 210A and the second smart meter 210B for measuring renewable power produced and renewable power consumed, respectively. In some embodiments, the solar panels allocated to the at least one customer 202 are metered by using at least one of a smart metering and a net metering technology. The renewable power may be a power or electricity produced by using renewable sources of energy such as, but not limiting to, the Sun.

The first smart meter 210A and the second smart meter 210B may be associated with a same meter identifier as of a third smart meter (not shown) installed and assigned to the customer 202 by the city power provider 212 such as, but not limited to, the municipality. The city power provider 212 may keep a track of the first and second smart meters 210A-210B and may also install the third meter (not shown) for the customer 202 for metering units of consumed electricity or non-renewable power supplied by the city power provider 212. In some embodiments, the third smart meter is configured to measure and meter non-renewable power consumed by the customer 202. The non-renewable power may be a power or electricity produced by using non-renewable sources of energy such as, but not limiting to, the coal, petrol, diesel, and so forth.

The city power provider 212 supplies and provides the non-renewable power to the customer 202. In an exemplary scenario, when the first smart meter 210A has more units of renewable power produced (or solar energy produced) than a meter reading of the second smart meter 210B showing renewable power consumed, then these extra units may be used to adjust or pay for the units of consumed electricity as shown by a meter reading of the third meter. Further, the extra units of renewable power produced as metered by the first smart meter 210A may be used to pay bill of the city power provider 212 or other utility bills. In some embodiments, the extra units of solar energy may be saved for future use. In some embodiments, the customer 202 may sell the extra units of solar energy produced by the allocated solar energy generation resources to other users.

The virtual resource providing system 204 may attach one or more allocated solar panels to the first smart meter 210A and the second smart meter 210B that is identified with a same account identifier (ID) as provided to the customer 202 by the city power provider 212. The renewable energy/power produced by the allocated solar panels may cancel out the equivalent of energy consumed within a billing system of the city power provider 212. If there is a net balance on either of the first smart meter 210A and the second smart meter 210B, then the virtual resource providing system 204 may either trigger a balance due or a net credit to a customer account of the customer 202 at a published provider rate from the infrastructure provider 208 (also referred in as the grid provider).

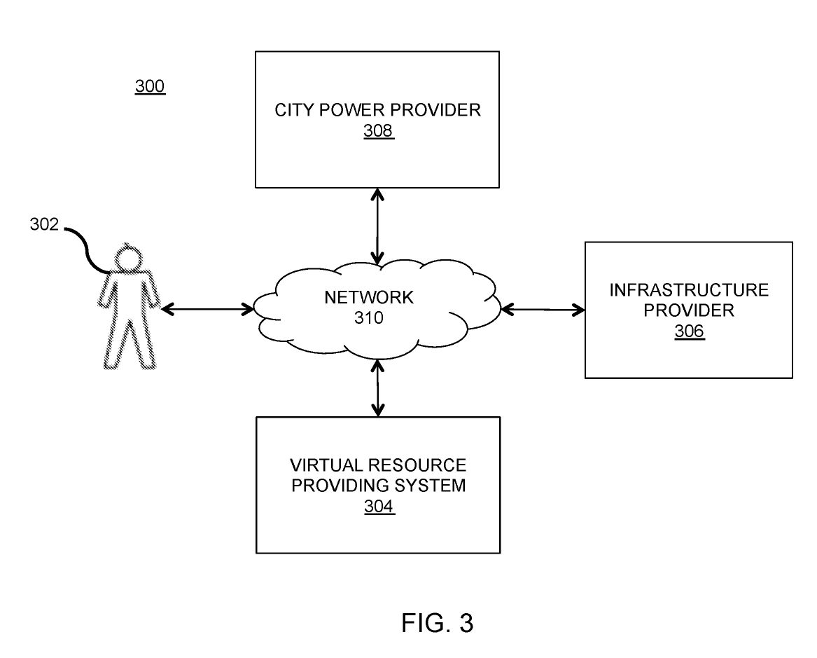

FIG. 3 illustrates another exemplary environment 300 where various embodiments of the present disclosure may function. As shown, the environment 300 includes a customer 302, a virtual resource providing system 304, an infrastructure provider 306, and a city power provider 308. The customer 302, the virtual resource providing system 304, the infrastructure provider 306, and the city power provider 308 may interact with each other via a network 310. The customer 302 can connect to the network 310 via a computing device (not shown) such as the computing device 106A of FIG. 1. The network 310 can be an Internet, a Local Area Network (LAN), a Wide Area Network (WAN), and so forth.

The customer 302 may enter a request at the computing device for one or more solar energy generation resources. The request may be received and processed by the virtual resource providing system 304. The virtual resource providing system 304 may provide or connect the infrastructure provider 306 with the customer 302 based on the request. The infrastructure provider 306 may provide infrastructure required for generating renewable power to the customer 302. The renewable power may be a power or electricity produced by using renewable sources of energy such as, but not limiting to, the Sun. The infrastructure may include one or more solar energy generation resources including a plurality of solar panels, a wiring, an invertor, an AC/DC converter, a grid access, ATS switching devices, an end-to end service, a health monitoring service, a first smart meter (such as the first smart meter 210A), and a second smart meter (such as the second smart meter 210B). The first smart meter may be installed at a premise of the infrastructure provider 306 and may meter or measure the renewable power produced by solar energy generation resources allocated to the customer 302. The second smart meter may be installed at a premise or home of the customer 302 and may meter or measure the renewable power consumed by the customer 302. In some embodiments, the city power provider 308 may also install a third meter, which is connected to the first and the second smart meters for recording usage and production of the power. The renewable power produced may be cancelled out by the city power provider for an equivalent of non-renewable energy/power consumed within a billing system of the city power provider by the customer 302. In some embodiments, the first smart meter and the second smart meter may directly upload the power production and power usage data or readings to the city power provider 308. In such scenarios, the city power provider 308 may cancel out the equivalent of energy consumed within a billing (or bill) system of the city power provider 308. Further, if there is a net balance on either of the first smart meter and the second smart meter, then the infrastructure provider 306 may trigger or maintain a balance due or a net credit to the customer 302 in his/her associated account at a published provider rate. In some embodiments, the first, second, and the third meters have a same identifier provided by the city power provider 308.

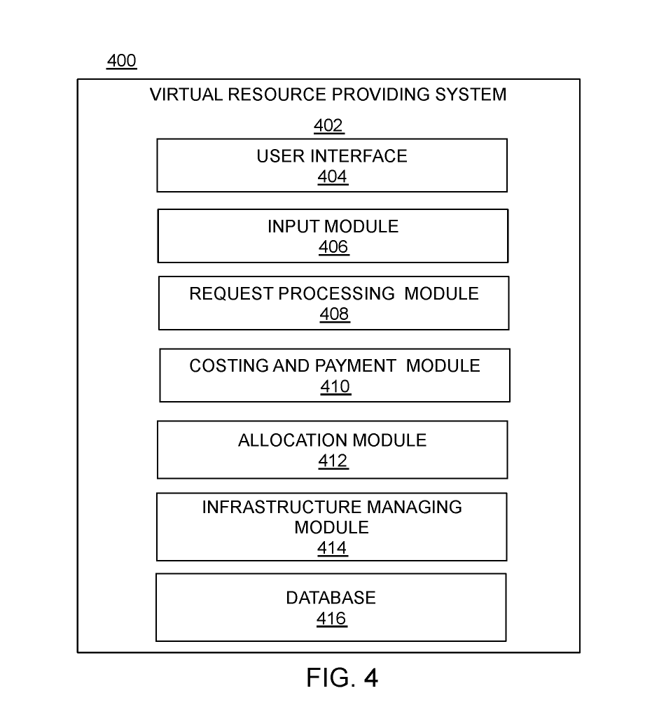

FIG. 4 is a block diagram 400 illustrating system elements of an exemplary virtual resource providing system 402, in accordance with an embodiment of the present disclosure. As shown, the virtual resource providing system 402 includes a user interface 404, an input module 406, a request processing module 408, a costing and payment module 410, an allocation module 412, an infrastructure managing module 414, and a database 416. A person ordinarily skilled in the art will understand that the virtual resource providing system may include more or less number of modules than shown.

As discussed with reference to FIG. 2, the customer 202 is configured to send a request to the virtual resource providing system 402 via a suitable computing device such as a smart phone. In some embodiments, the customer 202 may enter the request including a solar energy requirement and a billing information or other details via the user interface 404. The user interface 404 enables the customer 202 to interact with the virtual resource providing system 402 by using the computing device 206. The input module 406 is configured to receive the request comprising at least one of a solar energy requirement and a billing information from the customer 202. In some embodiments, the customer 202 provides the solar energy requirement and the billing information via the user interface 404.

The request processing module 408 is configured to process the request by identifying and presenting a list of plurality of infrastructure providers to the customer 202 based on the request. The customer 202 may select at least one infrastructure provider such as the infrastructure provider 208 from the list.

The costing and payment module 410 is configured to determine an infrastructure cost including a one-time materials' cost and a maintenance cost. The one-time materials' cost may include a cost of one or more solar energy generation resources including a number of solar panels, a wiring, an invertor, an AC/DC converter, a grid access, ATS switching devices, an end-to end service, a health monitoring service, a first smart meter (see 210A of FIG. 2), and a second smart meter (see 210B of FIG. 2) based on the received request. The costing and payment module 410 is also configured to receive a payment for the one or more solar energy generation resources according to the infrastructure cost from the customer 202. In some embodiments, the payment is received via a payment gateway (not shown).

The allocation module 412 is configured to allocate the one or more solar energy generation resources according to the received request to a customer account associated with the customer 202. The one or more solar energy generation resources may be located remotely from the customer 202 and are managed by the infrastructure provider 208 on behalf of the customer 202. The plurality of solar panels allocated to the customer 202 may be metered by using at least one of a smart metering and a net metering technology.

The allocation module 412 may be configured to at least one of install and allocate the one or more solar energy generation resources on behalf of the customer 202 at a centrally managed location of the infrastructure provider 208 as per the received request. Further, the plurality of solar panels may be installed at a centrally managed location/premise of the infrastructure provider 208, that is cost effective, have easy access to the full daylight sun and receive the sunlight in abundance for generating renewable power all through the year. The allocation module 412 may also be configured to assign a unique resource identifier to the allocated one or more solar energy generation resources.

The allocation module 412 may also be configured to attach the plurality of solar panels with the first smart meter 210A and the second smart meter 210B for measuring renewable power produced and renewable power consumed, respectively. The first smart meter 210A and the second smart meter 210B are associated with a same meter identifier assigned by a city power provider, such as the city power provider 212, comprising a municipality. The renewable power may be a power or electricity produced by using renewable sources of energy such as, but not limiting to, the Sun. In some embodiments, the allocation module 412 is also configured to de-allocate the one or more solar energy generation resources based on a de-allocation request received from the customer 202.

The infrastructure managing module 414 is configured to manage the one or more solar energy generation resources on behalf of the customer 202 to ensure operations and a consistent solar energy flow. Further, the infrastructure managing module 414 is configured to provide a plurality of support services including a repairing service, and a warranty service to the customer 202 post allocation of the one or more solar energy generation resources.

The database 416 may be configured to store information of plurality of customer accounts of the plurality of customers (such as the customer 202 of FIG. 2, customers 102A-102N of FIG. 1), a plurality of computing devices (such as the computing device 206, and the computing devices 106A-106N) associated with the plurality of customers, the plurality of infrastructure providers (such as the infrastructure provider 208 and 108), a login credential of each of the plurality of customers, a consumption and production information of the solar energy for each of the plurality of customers, and the plurality of solar energy generation resources.

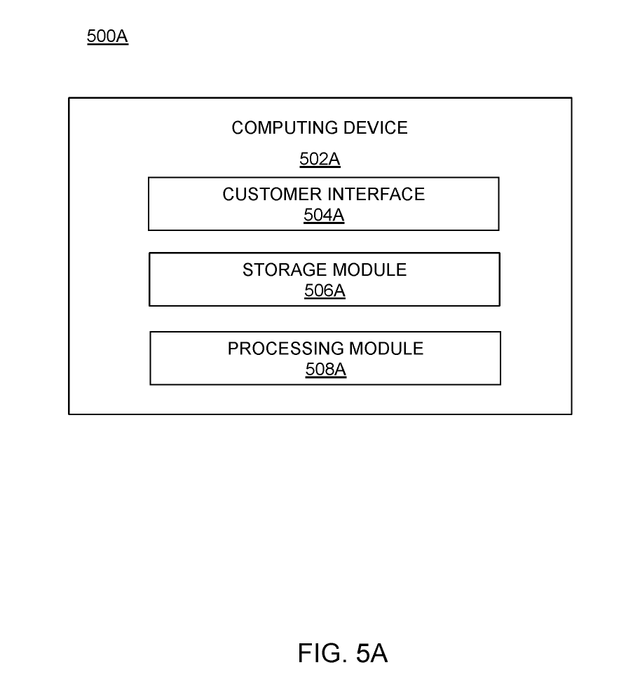

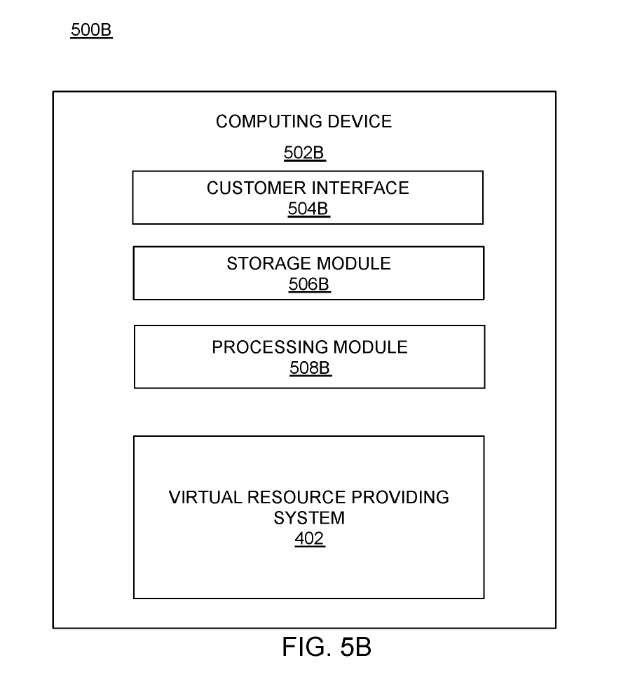

FIG. 5A is a block diagram 500A illustrating system elements of an exemplary computing device 502A, in accordance with an embodiment of the present disclosure. As shown, the computing device 502A includes a customer interface 504A, a storage module 506A, and a processing module 508A.

The customer interface 504A may enable the customer 202 to enter one or more inputs on the computing device 502A. The customer 202 may access a virtual resource providing system, such as the system 204 of FIG. 2, on a computing device, such as the computing device 502A, for entering a request comprising at least one of a solar energy requirement and a billing information. In some embodiments, the customer 202 enters the request via the customer interface.

The storage module 506A may store the details about accessing the virtual resource processing system 204. Further, the storage module 506A may store one or more instructions for entering the request and information received from the city power provider 212, the infrastructure provider 208, allocated the one or more solar energy generation resources. The one or more solar energy generation resources comprises a number of solar panels, a wiring, an invertor, an AC/DC converter, a grid access, ATS switching devices, an end-to end service, a health monitoring service, a first smart meter, and a second smart meter based on the received request.

The processing module 508A may be configured to process the input received from the customer 202. The processing module 508A is also configured to manage display on a screen of the computing device 502A.

FIG. 5B is a block diagram 500B illustrating system elements of another exemplary computing device 502B including the virtual resource providing system 402 of FIG. 4, in accordance with another embodiment of the present disclosure. In some embodiments, as shown, a computing device 502B may include the customer interface 504B, the storage module 506B, the processing module 508B, and the virtual resource providing system 402. The virtual resource providing system 402 may be an application stored and running on the computing device 502B.

Further, the storage module 506B is similar in functionality and structure to the storage module 506A of FIG. 5A. Additionally, the storage module 506B may store the virtual resource providing system 402. The processing module 508B is similar in functionality and structure to the processing module 508A of FIG. 5A.

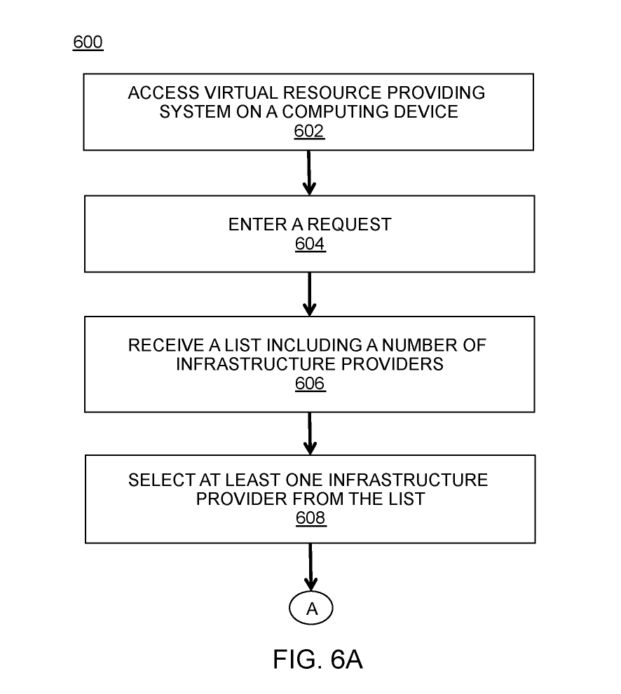

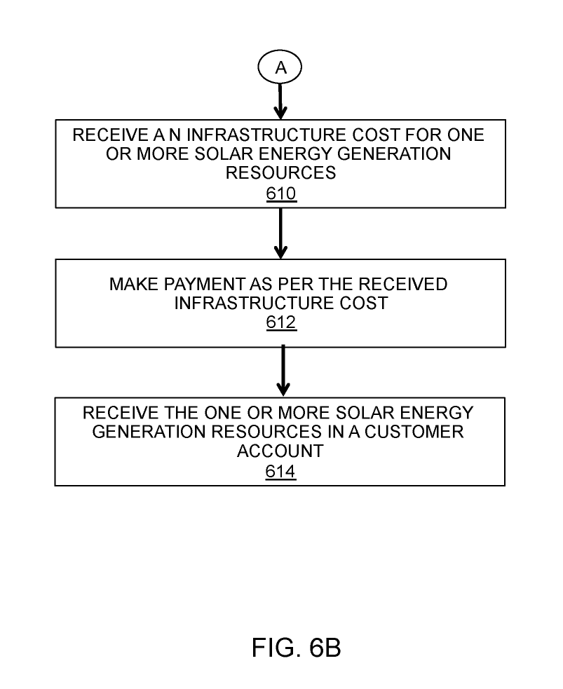

FIGS. 6A-6B illustrates a flowchart of a method 600 of buying, by a customer, one or more solar energy generation resources as a service by using the virtual resource providing system 402 of FIG. 4, in accordance with an embodiment of the present disclosure. At step 602, a customer accesses the virtual resource providing system on a computing device. Then, at step 604, the customer enters a request via a customer interface. The request may include at least one of a solar energy requirement, a billing information, and other details.

Then at step 606, the customer receives a list including a number of infrastructure providers capable of providing one or more solar energy generation resources as per the request. At step 608, the customer selects at least one infrastructure provider from the list of the infrastructure providers. Then at step 610, the customer receives, at the computing device, an infrastructure cost comprising a one time materials' cost and a maintenance cost for one or more solar energy generation resources. Then at step 612, the customer makes a payment as per the received infrastructure cost. Thereafter, at step 614, the customer receives the one or more solar energy generation resources in an associated customer account.

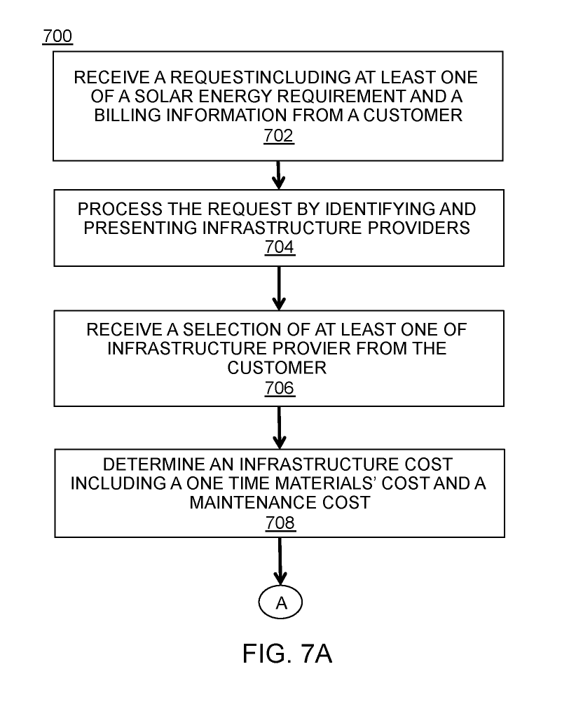

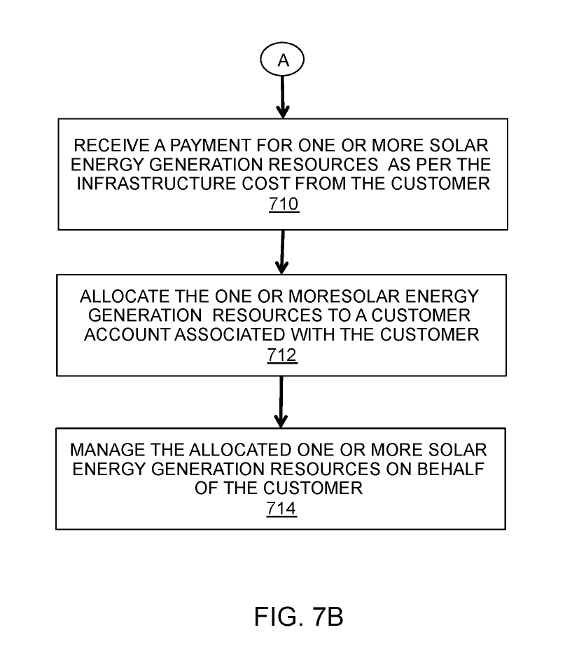

FIGS. 7A-7B illustrates a flowchart of a method 700 of selling and managing, by an infrastructure provider, one or more solar energy generation resources as a service by using the virtual resource providing system 402 of FIG. 4, in accordance with an embodiment of the present disclosure. At step 702, the virtual resource providing system 402 receives a request including at least one of a solar energy requirement, a billing information, and other details from a customer. In some embodiments, the input module 406 receives the request.

Then at step 704, the request is processed by identifying and presenting a number of infrastructure providers on a computing device of the customer. In some embodiments, the request may be processed by the request processing module 408. The customer can select at least one infrastructure provider from the infrastructure providers. Then at step 706, a selection of the at least one infrastructure provider is received by the input module 406. Then at step 708, an infrastructure cost including a one time materials' cost and maintenance cost. In some embodiments, the costing and payment module 410 determines a maintenance cost.

Thereafter at step 710, a payment for one or more solar energy generation resources is received as per the infrastructure cost from the customer. Then at step 712, the one or more solar energy generation resources are allocated to a customer account associated with the customer. Thereafter at step 714, the infrastructure provider manages the allocated one or more solar energy generation resources on behalf of the customer.

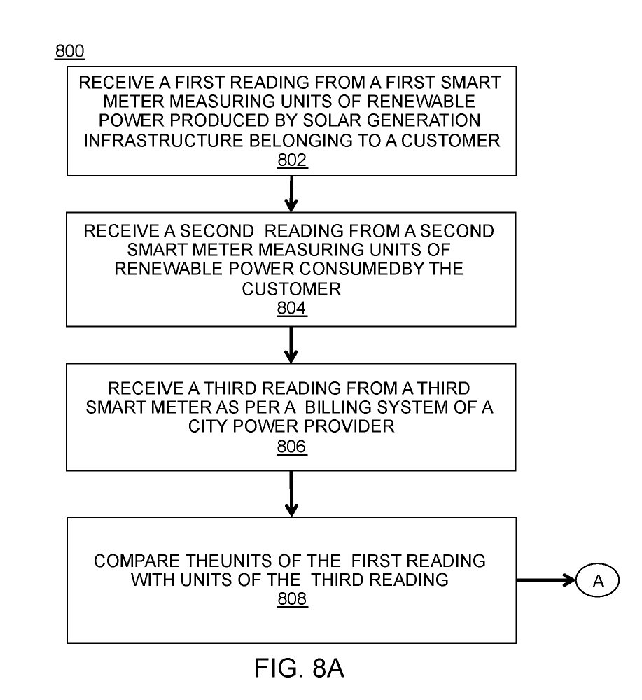

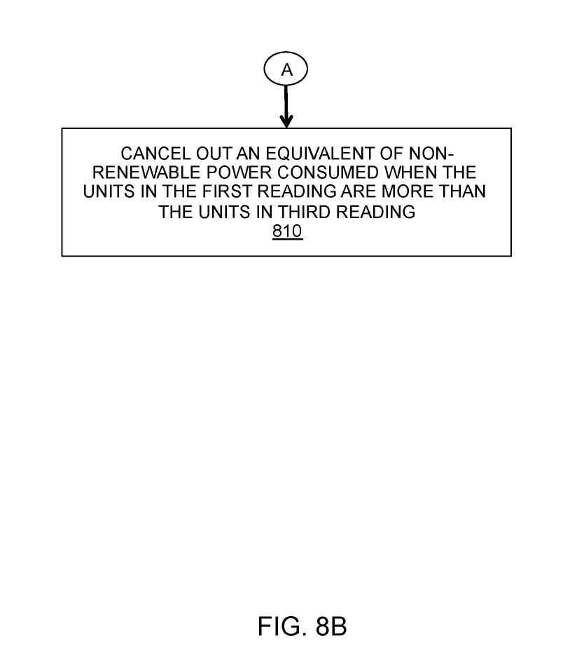

FIGS. 8A-8B illustrates a flowchart of a method 800 of adjusting units of renewable power produced for one or more units of non-renewable power supplied to a customer by a city power provider, in accordance with an embodiment of the present disclosure. The customer can be the customer 202 and the city power provider can be the city power provider 212 as discussed with reference to FIG. 2. The renewable power may be a power or electricity produced by using renewable sources of energy such as, but not limiting to, the Sun. Further, the renewable power may be produced by the solar energy generation resources or infrastructure allocated to a customer. The non-renewable power may be a power or electricity produced by using non-renewable sources of energy such as, but not limiting to, the coal, petrol, and so forth at a premise of the city power provider 212. The city power provider 212 may supply non-renewable power to a premise of the customer 202 and may be metered by a third smart meter.

At step 802, the city power provider 212 receives a first reading of the first smart meter 210A measuring units of renewable power produced by solar energy generation infrastructure belonging to the customer 202. The first smart meter 210A may be installed at a premise of an infrastructure provider, such as the infrastructure provider 208, may meter the renewable power produced by one or more solar energy generation resources or infrastructure allocated to a customer such as, the customer 202.

At step 804, the city power provider 212 receives a second reading of the second smart meter 210B measuring renewable power consumed by the customer 202. The second smart meter 210B is installed at a premise of the customer 202 and may meter renewable power consumed by the customer 202.

Then at step 806, the city power provider 212 receives a third reading of a third smart meter as per a billing system of the city power provider 212. The third smart meter may be installed by the city power provider 212 at the premise of the customer 202 and is assigned with a unique ID which may be same as that of the first smart meter 210A and the second smart meter 210B. The first smart meter 210A, the second smart meter 210B, and the third smart meter 210C are assigned with the same identifier and are attached with a same user account ID of the customer 202.

Then at step 808, units of the first reading are compared with units of the third reading. The reading data of the first smart meter 210A and the second smart meter 210B may be automatically uploaded to the city power provider 212 for balancing the units of the third smart meter. Thereafter, an equivalent amount of non-renewable power consumed by the customer 202 is cancelled out when the units in the first reading are more than the units in the third reading. this means when the solar energy generation resources or infrastructure produces more renewable power then these extra units of renewable power may be used to pay bill of units of non-renewable power supplied by the city power provider 212.

The present disclosure provides methods and systems for selling one or more solar energy generation resources/infrastructure to the customers 102A-102N by the infrastructure providers 108A-108N as a service. The renewable power produced by the allocated solar energy generation resources/infrastructure may be supplied to and used by the customer. Further, the renewable power produced is metered by the first smart meter 210A and renewable power consumed is metered by the second smart meter 210B. In some embodiments, the extra units of renewable power produced may be cancel out units of non-renewable power provided to the customers 102A-102N by the city power provider 212 and metered by a third smart meter. The non-renewable power may be a power or electricity produced by using non-renewable sources of energy such as, but not limiting to, coal, petrol, and so forth.

In an embodiment of the present disclosure, the customers 102A-102N may save the un-used renewable power for future use. In some embodiments, the customers 102A-102N can sell the un-used renewable power to other users. In some embodiments, the customers 102A-102N can pay their utility bills such as, but not limited to, an electricity bill by using the un-used renewable power which is produced by the solar energy generation resources or infrastructure purchased by the customers 102A-102N.

In some embodiments, the customers 102A-102N can check their renewable power balance available via the virtual resource providing system 104.

An advantage of the present disclosure includes that the customers 102A-102N may need not to own any on-site hardware and panels. Further, the customers 102A-102N may need not to modify existing building architecture or its look where renewable power is consumed.

Another advantage of the present disclosure for the customers 102A-102N includes cost-effectiveness. The shared services such as, shared inverters, monitoring software, panel racks, charge controllers actually work out less costly to the customer than to own these resources individually.

Yet another advantage of the present disclosure includes supplying energy to outside city areas easily. As the solar energy generation infrastructure of the infrastructure providers 108A-108N may be located on land with ideal irradiance levels outside the city center and situated near grids further upstream so that the farm can deliver renewable power where the city power provider 212 needs it most.

The presently disclosed and systems and methods enables the customers 102A-102N make money over time and create renewable energy for free. Further, the current return on investment (ROI) for today's solar panels is 5-6 years, and this ROI may remain same. This may allow the customers 102A-102N that own 25 year Grade-A rated panels to make money on their investment over time and create free renewable power or energy for them after their investment has been recuperated.

Further, the disclosed virtual resources providing system 204 enables the customer 202 with flexibility of changing his/her address when he/she changes his/her homes. For example, the customer 202 decides to move, instead of having to uninstall and reinstall his/her allocated solar panels and other resources at a new location, the customer 202 can simply update his/her new meter identifier on the virtual resource providing system 204 and resume receiving the benefits of his/her allocated solar panels at his/her new address.

The presently disclosed systems and methods allow the customers 102A-102N to invest alongside the city power provider 212 (i.e. the Municipality) for energy/power independence.

The presently disclosed systems and methods may enable the customers 102A-102N to reduce the time it may take to go zero carbon footprint to hours from weeks or months.

Further, the presently disclosed systems and methods may allow the city power provider 212 to use land that might go otherwise unused, and generate revenue from it by allocating it to the infrastructure providers 208A-208N.

Further, the presently disclosed systems and methods may enable the city power provider 212 to mandate advanced levels of green energy consumption without worrying about its feasibility to the customers 102A-102N (or 202).

Further, the presently disclosed systems and methods may allow the customers 102A-102N to invest alongside the city power provider 212 for renewable energy/power independence.

Furthermore, the presently disclosed systems and methods results in quick adaption across all types of customers 102A-102N due to ease of use and development.

Further, the presently disclosed systems and methods may enable the city power provider 212 to free up cash at their end as they can redeploy their financial resources from traditional fossil fuel power plant provisioning to other projects or initiatives.

Embodiments of the disclosure are also described above with reference to flowchart illustrations and/or block diagrams of methods and systems. It will be understood that each block of the flowchart illustrations and/or block diagrams, and combinations of blocks in the flowchart illustrations and/or block diagrams, may be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the acts specified in the flowchart and/or block diagram block or blocks. These computer program instructions may also be stored in a computer-readable memory that can direct a computer or other programmable data processing apparatus to operate in a particular manner, such that the instructions stored in the computer-readable memory produce an article of manufacture including instruction means which implement the acts specified in the flowchart and/or block diagram block or blocks. The computer program instructions may also be loaded onto a computer or other programmable data processing apparatus to cause a series of operations to be performed on the computer or other programmable apparatus to produce a computer implemented process such that the instructions which execute on the computer or other programmable apparatus provide steps for implementing the acts specified in the flowchart and/or block diagram block or blocks.

In addition, methods and functions described herein are not limited to any particular sequence, and the acts or blocks relating thereto can be performed in other sequences that are appropriate. For example, described acts or blocks may be performed in an order other than that specifically disclosed, or multiple acts or blocks may be combined in a single act or block.

While the invention has been described in connection with what is presently considered to be the most practical and various embodiments, it is to be understood that the invention is not to be limited to the disclosed embodiments, but on the contrary, is intended to cover various modifications and equivalent arrangements.

What is claimed is:

1. A system for providing, by an infrastructure provider, a solar energy generation infrastructure to a plurality of customers as a service, the system comprising:
an input module configured to receive a request comprising at least one of a solar energy requirement and a billing information from at least one customer of the plurality of customers;
a request processing module configured to process the request by identifying and presenting a list of plurality of infrastructure providers to the at least one customer based on the request, wherein the at least one customer selects at least one infrastructure provider from the list;
a costing and payment module configured to:
determine an infrastructure cost comprising a one-time materials' cost and a maintenance cost, the one-time materials' cost comprising a cost of one or more solar energy generation infrastructure comprising a plurality of solar panels, a wiring, an invertor, an AC/DC converter, a grid access, ATS switching devices, an end-to end service, a health monitoring service, a first smart meter, and a second smart meter based on the received request; and
receive a payment for the one or more solar energy generation infrastructure according to the infrastructure cost from the at least one customer via a payment gateway; and
an allocation module configured to allocate the one or more solar energy generation infrastructure according to the received request to a customer account associated with the at least one customer.

2. The system of claim 1 further comprising a database configured to store information of plurality of customer accounts of the plurality of customers, a plurality of computing devices associated with the plurality of customers, the plurality of infrastructure providers, a login credential of each of the plurality of customers, a consumption and production information of the solar energy for each of the plurality of customers, and the plurality of solar energy generation infrastructure.

3. The system of claim 2, wherein the plurality of customers comprises at least one of a plurality of industries, and an individual person.

4. The system of claim 1, wherein the one or more solar energy generation infrastructure is located remotely on from the at least one customer and are managed by the infrastructure provider on behalf of the at least one customer.

5. The system of claim 1, wherein the plurality of solar panels allocated to the at least one customer is metered by using at least one of a smart metering and a net metering technology.

6. The system of claim 1, wherein the allocation module is further configured to:
at least one of install and allocate the one or more solar energy generation infrastructure on behalf of the at least one customer at a centrally managed location of the at least one infrastructure provider as per the received request;
assign a unique resource identifier to the allocated one or more solar energy generation infrastructure for identifying the one or more solar energy generation infrastructure belonging to the at least one customer; and
attach the plurality of solar panels with the first smart meter and the second smart meter for measuring renewable power produced and renewable power consumed, respectively, wherein the first smart meter and the second smart meter are associated with a same meter identifier assigned by a city power provider comprising a municipality.

7. The system of claim 6, wherein the centrally managed location of the infrastructure provider is cost effective, have easy access to the full daylight sun and receive the sunlight in abundance for generating renewable power.

8. The system of claim 1 further comprising an infrastructure managing module configured to:
manage the one or more solar energy generation infrastructure on behalf of the at least one customer to ensure the operations of the same and a consistent solar energy flow; and
provide a plurality of support services comprising a repairing service, and a warranty service to the at least one customer post allocation of the one or more solar energy generation infrastructure.

9. The system of claim 1, wherein the allocation module is also configured to de-allocate the one or more solar energy generation infrastructure based on a de-allocation request received from the at least one customer.

10. The system of claim 1 wherein the system comprising:
an input module configured to receive a request comprising at least one of a solar energy requirement and a billing information from at least one customer of the plurality of customers, wherein the at least one customer provides the solar energy requirement and the billing information via a customer interface;
a request processing module configured to process the request by identifying and presenting a list of plurality of infrastructure providers to the at least one customer based on the request, wherein the at least one customer selects at least one infrastructure provider from the list;
a costing and payment module configured to:
determine an infrastructure cost comprising a one-time materials' cost and a maintenance cost, the one-time materials' cost comprising a cost of one or more solar energy generation resources comprising a plurality of solar panels, a wiring, an invertor, an AC/DC converter, a grid access, ATS switching devices, an end-to end service, a health monitoring service, a first smart meter, and a second smart meter based on the received request; and
receive a payment for the one or more solar energy generation resources according to the infrastructure cost from the at least one customer;
an allocation module configured to allocate the one or more solar energy generation resources according to the received request to a customer account associated with the at least one customer; and
an infrastructure managing module configured to:
manage the one or more solar energy generation resources on behalf of the at least one customer to ensure operations and a consistent solar energy flow; and
provide a plurality of support services comprising a repairing service, and a warranty service to the at least one customer post allocation of the one or more solar energy generation resources.

11. The system of claim 10 further comprising a database configured to store information of plurality of customer accounts of the plurality of customers, a plurality of computing devices associated with the plurality of customers, the plurality of infrastructure providers, a login credential of each of the plurality of customers, a consumption and production information of the solar energy for each of the plurality of customers, and the plurality of solar energy generation resources.

12. The system of claim 11, wherein the plurality of customers comprises at least one of a plurality of industries, and an individual person.

13. The system of claim 11, wherein the payment is received via a payment gateway.

14. The system of claim 11, wherein the one or more solar energy generation resources are located remotely from the at least one customer and are managed by the infrastructure provider on behalf of the at least one customer.

15. The system of claim 11, wherein the plurality of solar panels allocated to the at least one customer is metered by using at least one of a smart metering and a net metering technology.

16. The system of claim 10, wherein the allocation module is further configured to:
at least one of install and allocate the one or more solar energy generation resources on behalf of the at least one customer at a centrally managed location of the at least one infrastructure provider as per the received request;
assign a unique resource identifier to the allocated one or more solar energy generation resources; and
attach the plurality of solar panels with the first smart meter and the second smart meter for measuring renewable power produced and renewable power consumed, respectively, wherein the first smart meter and the second smart meter are associated with a same meter identifier assigned by a city power provider comprising a municipality.

17. The system of claim 16, wherein the centrally managed location of the infrastructure provider is cost effective, have easy access to the full daylight sun and receive the sunlight in abundance for generating renewable power.

18. The system of claim 11, wherein the allocation module is also configured to de-allocate the one or more solar energy generation resources based on a de-allocation request received from the at least one customer.

19. A virtual resource providing system for selling a plurality of solar energy generation resources installed at a centrally managed location of an infrastructure provider as a service on behalf of a plurality of customers for generating renewable power, the system comprising:
an input module configured to receive a request comprising at least one of a solar energy requirement and a billing information from at least one customer of a plurality of customers, wherein the at least one customer provides the solar energy requirement via a customer interface;
a request processing module configured to process the request by identifying and presenting a list comprising a plurality of infrastructure providers to the at least one customer based on the request, wherein the at least one customer selects at least one infrastructure provider from the list;
a costing and payment module configured to:
determine an infrastructure cost comprising a one-time materials' cost and a maintenance cost, the one-time materials' cost comprising a cost of one or more solar energy generation resources comprising a plurality of solar panels, a wiring, an invertor, an AC/DC converter, a grid access, ATS switching devices, an end-to end service, a health monitoring service, a first smart meter, and a second smart meter based on the received request; and
receive a payment for the one or more solar energy generation resources according to the infrastructure cost from the at least one customer;
an allocation module configured to allocate the one or more solar energy generation resources according to the received request to a customer account associated with the at least one customer; and
an infrastructure managing module configured to:
manage the one or more solar energy generation resources on behalf of the at least one customer to ensure operations and a consistent solar energy flow; and
provide a plurality of support services comprising a repairing service, and a warranty service to the at least one customer post allocation of the one or more solar energy generation resources.

20. A method for selling a plurality of solar energy generation resources as a service to a plurality of customers, the method comprising:
receiving, by an input module, a request comprising at least one of a solar energy requirement and a billing information from at least one customer of the plurality of customers, wherein the at least one customer provides the solar energy requirement via a customer interface;
processing, by a request processing module, the request by identifying and presenting a plurality of infrastructure providers to the at least one customer based on the request, wherein the at least one customer selects at least one infrastructure provider of the plurality of infrastructure providers;
determining, by a costing and payment module, an infrastructure cost comprising a one-time materials' cost and a maintenance cost, the one-time materials' cost comprising a cost of one or more solar energy generation resources comprising a plurality of solar panels, a wiring, an invertor, an AC/DC converter, a grid access, ATS switching devices, an end-to end service, a health monitoring service, a first smart meter, and a second smart meter based on the received request;
receiving, by the costing and payment module, a payment for the one or more solar energy generation resources according to the infrastructure cost from the at least one customer; and
allocating, by an allocation module, the one or more solar energy generation resources according to the received request to a customer account associated with the at least one customer.
